(19) United States
(12) Patent Application Publication
(10) Pub. No.: US 2025/0277301 A1
(43) Pub. Date: Sep. 4, 2025

(54) COATING SYSTEM AND METHOD FOR SEMICONDUCTOR EQUIPMENT COMPONENTS

(71) Applicant: Oerlikon Surface Solutions AG, Pfäffikon, Pfäffikon (CH)

(72) Inventors: SIEGFRIED KRASSNITZER, FELDKIRCH (AT); JUERGEN GWEHENBERGER, SEVELEN (CH); JUERG HAGMANN, SAX (CH); MARTIN SCHMID, JENAZ (CH); DOMINIK ERWIN WIDMER, VILTERS (CH); MATTHEW PAUL KIRK, LOCKPORT, NY (US); JULIEN KERAUDY, BUCHS (CH); SEBASTIEN GUIMOND, ST. GALLEN (CH); JOHN CONIFF, QUEEN CREEK, AZ (US)

(21) Appl. No.: 18/858,996

(22) PCT Filed: Apr. 20, 2023
(86) PCT No.: PCT/EP2023/000023

§ 371 Date: Oct. 22, 2024

Related U.S. Application Data
(60) Provisional application No. 63/363,395, filed on Apr. 22, 2022.

(51) Int. Cl. C23C 14/35; C23C 14/50; H01J 37/32; H01J 37/34

(52) U.S. Cl. CPC C23C 14/35; C23C 14/505; H01J 37/32825; H01J 37/3405; H01J 2237/20214; H01J 2237/332

(57) ABSTRACT

An apparatus for coating a component. The apparatus includes a chamber. A first magnetron and a second magnetron are disposed within the chamber for supplying a coating material to a surface of the component. A component holder is disposed within the chamber and is configured to hold the component. The first magnetron and the second magnetron are configured to be positioned and oriented adjacent the surface of the component held by the component holder and the first and second magnetrons are configured to move with respect to the component holder or the component holder is configured to move with respect to the first and second magnetrons during coating of the component.

### FIELD OF THE INVENTION

The present invention relates to applying coatings on semiconductor equipment, for example, liners, shutters, doors, dielectric windows and electrostatic chucks. In particular, the present invention provides a method and apparatus for applying a protective coating uniformly on surfaces of the semiconductor equipment components that are exposed to plasma to help protect the equipment against wear and chemical attack.

### Background of Invention

Semiconductor equipment used to produce semiconductor devices is subject to heavy wear and chemical attack due to their repeated exposure to plasma during manufacturing, especially in the case of plasma etching. The etching, clamping and de-clamping of these components may result in wear and the accumulation of particles, i.e., debris on the surface of a wafer be processed. The accumulation of particles can contaminate the wafers and result in the wafers being discarded or re-processed.

The chemical attack on the semiconductor equipment is typically caused by highly reactive fluorine or chlorine chemicals. The attack by these chemicals is particularly intensified during plasma discharge. In some applications, protection from fluorine is accomplished by coating the components with Y₂O₃ or YOF layers using thermal spraying or aerosol spraying methods. These coatings usually have a thickness of approx. 100 μm. However, because of the porous nature of these coatings it is usually necessary to make the coating thick to protect the underlying component.

Mechanical wear typically is observed during repetitive processing of wafers on an electrostatic chuck. Dots of ceramic material, so called mesa structure, usually experience wear during the repetitive processing. Electrostatic chucks are costly components and it is highly desirable to refurbish the depleted up mesa structure.

It is desirable to have a method and apparatus for applying an etch resistant protective layer or a hard, wear resistant ceramic layer to semiconductor equipment components using physical vapor deposition (PVD) coating technology.

### SUMMARY OF THE INVENTION

There is provided an apparatus for coating a component. The apparatus includes a chamber. A first magnetron and a second magnetron are disposed within the chamber for supplying a coating material to a surface of the component. A component holder is disposed within the chamber and is configured to hold the component. The first magnetron and the second magnetron are configured to be positioned and oriented adjacent the surface of the component held by the component holder and the first and second magnetrons are configured to move with respect to the component holder or the component holder is configured to move with respect to the first and second magnetrons during coating of the component.

In the foregoing apparatus, the orientation of the first and second magnetrons with respect to the surface of the component held by component holder is configured to be changeable with respect to the component holder.

In the foregoing apparatus, the movement of the first and second magnetron with respect to the component holder can be realized in that the component holder is configured in a fix position and the first magnetron and the second magnetron are configured to move during the coating of the component. The fix position of the component holder preferably excludes translational movement as well as rotational movement with respect to the chamber.

The movement of the first and second magnetrons with respect to the component holder can be used to improve the coating thickness distribution over the surface of the component. In particular, to allow coating of surfaces of the component where it is otherwise difficult to attain a homogeneous coating thickness distribution.

For increased process efficiency, the movement of the first and second magnetrons with respect to the component holder may be performed while the magnetrons are operating.

In the foregoing apparatus, the component is an electrostatic chuck or window and forms at least part of the coating chamber wall, preferably is a chamber wall.

In the foregoing apparatus, the first magnetron and the second magnetron are preferably operating with a power supply delivering Bi-polar pulses.

In the foregoing apparatus, the component can be for example a liner, an electrostatic chuck or a window.

The foregoing apparatus can further include a third magnetron and a fourth magnetron wherein the component is a liner and the first magnetron and the second magnetron are configured to be disposed adjacent an inner surface of the liner and the third magnetron and the fourth magnetron are configured to be disposed adjacent an outer surface of the liner.

In the foregoing apparatus, the first magnetron and the second magnetron depositing for example a film comprising or being Al₂O₃, AlN, AlOF, AlON, Y₂O₃, YAG, YOF, YF₃, Er₂O₃ or ErOF or a combination thereof, on the component by using a metallic target (e.g., Al, Y, AlY, Er, etc.) or a compound target (e.g., Al₂O₃, AlN, Y₂O₃, YF₃, Er₂O₃, etc.) to form the film by supplying a proper reactive gas mixture (e.g., N₂, O₂, O₂+N₂, CF₄, CF₄+O₂, etc.). However it is as well possible to deposit oxides, nitrides, fluorides, carbides and/or carbon-based coatings like DLC or doped DLC. In addition, multi-compound ceramic alloy (with more than 1, 2, 3 or even more metallic elements also referred as high entropy) can be deposited.

In the foregoing apparatus, the component holder can be a rotary assembly.

In the foregoing apparatus, the component holder can extend through a wall of the chamber.

In the foregoing apparatus, the component holder can be a wall of the chamber.

In the foregoing apparatus, the first and second magnetrons can be configured to rotate with respect to the component holder or the component holder can be configured to rotate with respect to the first and second magnetrons during coating of the component.

There is further provided a method for coating components. The method includes positioning a component holder in a coating chamber, the component holder configured to hold the component; positioning and orienting a first magnetron and a second magnetron within the coating chamber adjacent a surface of the component held by the component holder; and moving the component holder with respect to the first and second magnetrons or moving the first and second magnetrons with respect to the component holder while sputtering a material from the first magnetron and the second magnetron to the component.

In the foregoing method, the step of moving the component holder with respect to the first and second magnetrons or moving the first and second magnetrons with respect to the component holder can include changing the orientation of the first and second magnetrons with respect to the surface of the component held by the component holder as the component holder moves with respect to the first and second magnetrons or the first and second magnetrons move with respect to the component holder.

In the foregoing method, the step of moving the first and second magnetrons with respect to the component holder can include keeping the component holder is in a fix position while the first and the second magnetrons are moving with respect to the component holder. The fix position of the component holder preferably excludes translational movement as well as rotational movement with respect to the chamber.

In the foregoing method, the step of moving the component holder with respect to the first and the second magnetrons or moving the first and second magnetrons with respect to the component holder can include depositing a film comprising or being Al₂O₃, AlN, AlOF, AlON, Y₂O₃, YOF or YF₃, Er₂O₃, ErOF, DLC or doped DLC or a combination thereof, on the component. However it is as well possible to deposit oxides, nitrides, fluorides, carbides and/or carbon-based coatings. In addition, multi-compound ceramic alloy (with more than 1, 2, 3 or even more metallic elements also referred as high entropy) can be deposited.

In the foregoing method, the first magnetron and the second magnetron with a power supply delivering Bi-polar pulses.

The foregoing method, can further include deposition with a third magnetron and a fourth magnetron wherein the component is a liner and the first magnetron and the second magnetron are disposed adjacent an inner surface of the liner and the third magnetron and the fourth magnetron disposed adjacent an outer surface of the liner.

In the foregoing method, the component holder can be a rotary assembly.

In the foregoing method, the component holder can extend through a wall of the coating chamber.

In the foregoing method, the component holder can be a wall of the coating chamber. In particular, the component holder can be part of the wall that seals the interior of the coating chamber from the ambient. The component holder may as such for part of the vacuum sealing.

The arrangement of the component holder as part of the coating chamber has at least the advantage that the component holder can be equipped with a cooling circuit from the ambient side, without the need for a special feedthrough. One further advantage is that the component holder may be connected to an RF power supply from the ambient side in a simple and technically accessible way.

In the foregoing method, the step of moving the component holder with respect to the first and second magnetrons or moving the first and second magnetrons with respect to the component holder can include rotating the component holder with respect to the first and second magnetrons or rotating the first and second magnetrons with respect to the component holder.

### BRIEF DESCRIPTION OF THE DRAWINGS

FIG. 1 shows an open coating chamber with a movable pair of magnetrons, according to one embodiment of the present invention;

FIG. 2 shows the pair of magnetrons of FIG. 1 positioned and oriented to coat a liner;

FIG. 3a is a sectioned perspective view of the liner of FIG. 2, illustrating the coating on the liner;

FIG. 3b is a graph of the thickness of the coating of FIG. 3a along the liner;

FIG. 4a is a sectioned perspective view showing the pair of magnetrons (represented by oval dashed lines) positioned near two liners;

FIG. 4b is sectioned side view of the pair of magnetrons and the two liners of FIG. 4a;

FIG. 5 is a sectioned side view of a coating assembly, according to another embodiment of the present invention, illustrating an electrostatic chuck and a pair of magnetrons disposed within a chamber;

FIG. 6a is a sectioned side view of coating assembly showing a pair of magnetrons inside a liner;

FIG. 6b is a sectioned perspective view of the coating assembly of FIG. 6a;

FIG. 7 is a perspective view of a coating assembly, according to another embodiment of the present invention showing a first pair of magnetrons and a second pair of magnetrons positioned adjacent a liner;

FIG. 8a is a sectioned side view of a liner illustrating the positioning of a cooling contact on the liner; and

FIG. 8b is a section side view illustrating a temperature distribution for the liner of FIG. 8a.

### DETAILED DESCRIPTION OF PREFERRED EMBODIMENT

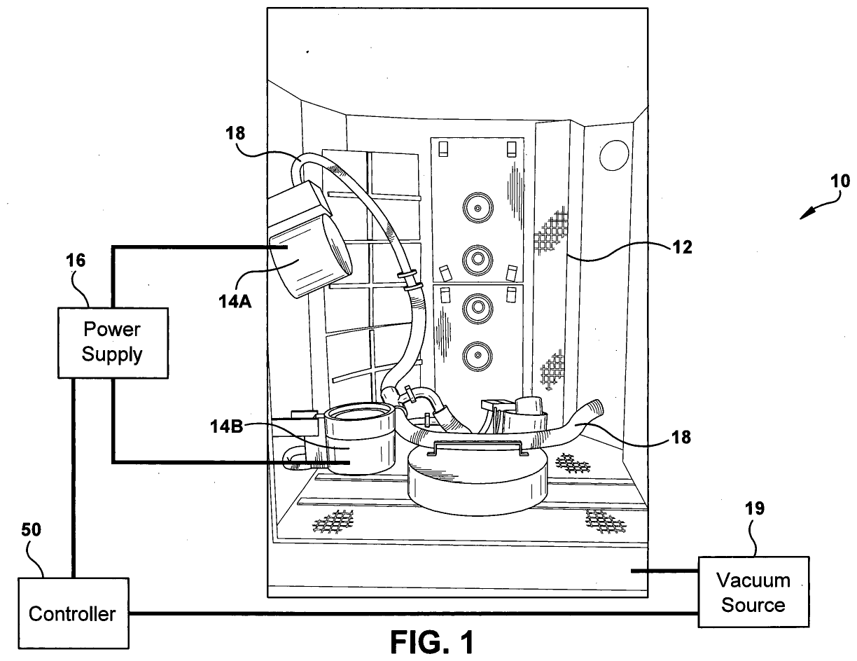

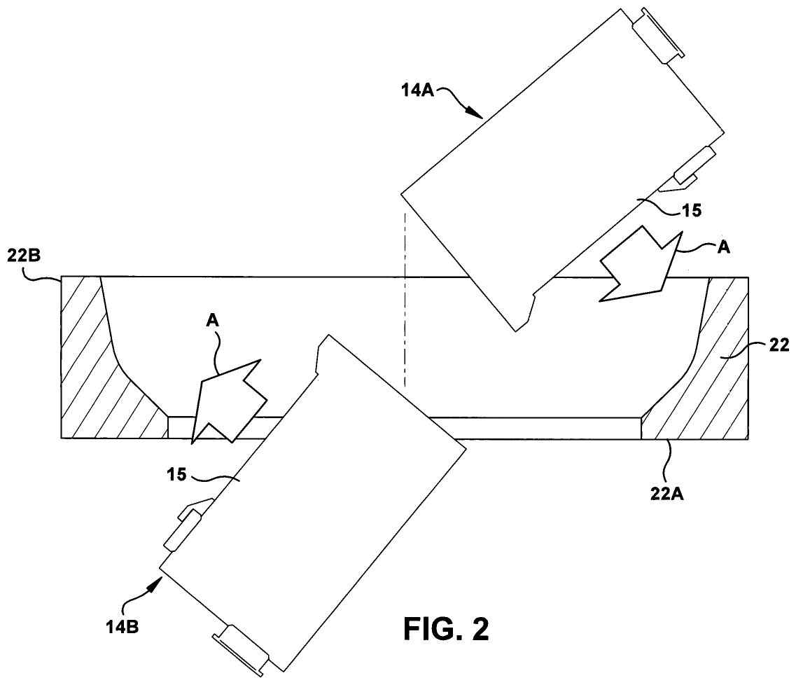

Referring to FIG. 1, an exemplary coating assembly 10, according to a first embodiment, is illustrated. The coating assembly 10 includes a chamber 12 that is configured to receive a component to be coated, e.g., a liner 22 (FIG. 2), a first magnetron 14A and a second magnetron 14B. A controller 50 is provided to control the operation of the coating assembly 10. The controller 50 assures that the working point of the reactive sputter process is stable with regard to sputter target poisoning and stoichiometry. A power supply 16 is positioned outside of the chamber 12 for providing preferably constant power to the first magnetron 14A and the second magnetron 14B keeping the voltage at a predefined value by regulating reactive gas flow upon command by the controller 50. It is contemplated that the power supply 19 may be a Bi-polar pulse generator that operates at a predetermined frequency, e.g., 50 kHz-100 kHz. The power supply 19 is configured and controlled such that during operation while one of the first magnetron 14A and the second magnetron 14B is sputtering (i.e., is an anode), the other of the first magnetron 14A and the second magnetron 14B is a cathode. Bi-polar sputtering has the advantage of stable electrical situation, because one target is always an anode not coated by an insulated layer, even in an oxygen reactive mode.

The coating assembly 10 also includes flexible tubes 18 that are positioned to supply high voltage and cooling media to the first magnetron 14A and the second magnetron 14B. The tubes 18 allow the first magnetron 14A and the second magnetron 14B to be adjusted freely in the vacuum space of the chamber 12.

The coating assembly 10 may include a door (not shown) for allowing a user to insert and remove a liner 22. The door (not shown) may seal the chamber 12 such that a vacuum maybe applied to the chamber 12 during processing via a vacuum source 19, e.g., a vacuum pump.

As illustrated in FIG. 1, the first magnetron 14A and the second magnetron 14B are positioned adjacent one wall of the chamber 12. It is contemplated that the first magnetron 14A and the second magnetron 14B may be positioned at various locations and orientations with respect to the liner 22. Referring to FIG. 2, the first magnetron 14A is positioned adjacent one side 22a of the liner 22 and the second magnetron 14B is positioned adjacent an opposite side 22b of the liner 22. The first and second magnetrons 14A, 14B are oriented such that the target surfaces 15 of the first and second magnetrons 14A, 14B direct material toward the adjacent side 22a, 22b, as represented by arrows A in FIG. 2. Although the first and second magnetrons 14A, 14B are illustrated as being stationary, it is contemplated that the first and second magnetrons 14A, 14B may rotate to apply sputter material to an entire periphery of the liner 22. Alternatively, the first and second magnetrons 14A, 14B may be stationary and the liner 22 (and a component holder that holds the liner 22, described in detail below) may rotate with respect to them. It is also contemplated that the orientation of the first and second magnetrons 14A, 14B with respect to the object to be coated may change, for example, wobble, as they rotate or as the liner 22 (and its component holder) rotates so that an entirety of the surface of the liner 22 is properly coated.

During the coating process, it is contemplated that the first and second magnetrons 14A, 14B and the gas supplied to the chamber 12 may be selected to deposit dense coatings of oxides, nitrides, or fluorides or oxy-fluorides of Yttrium, Erbium or other metal or metal alloys (e.g., Al—W, Al—Si, or multicomponent coating with 3, 4 5 or more metal elements)-oxides-oxyfluorides-fluorides or combinations thereof. For example, it is contemplated that films of Al₂O₃, AlN, AlOF, AlON, Y₂O₃, YOF, YF₃, Er₂O₃ or ErOF may be deposited on the liner 22.

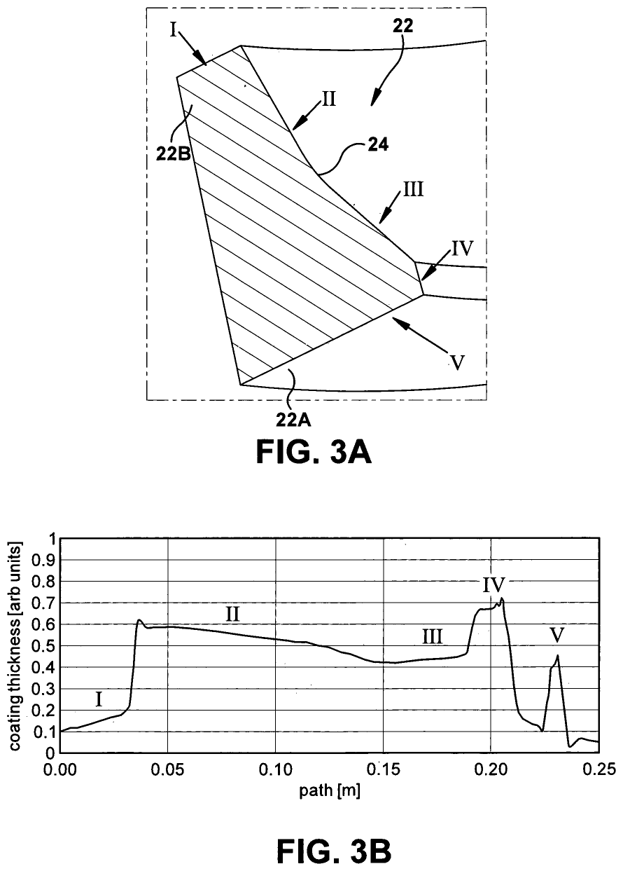

As described above, the first and second magnetrons 14A, 14B and/or the liner 22 move with respect to each other and the first and second magnetrons 14A, 14B are oriented such that the entire surface of the liner 22 that is exposed to a later etching process is coated with the desired film. Referring to FIG. 3a, a film 24 is illustrated as being applied to an inner surface of the liner 22. A thickness of the film 24 may vary along the surface of the liner 22. FIG. 3b illustrates an exemplary film thickness distribution along sections I-V of the inner surface of the liner 22. The exemplary film thickness distribution shows low thickness coverage on section I. In sections II-IV the film thickness is higher with a largely uniform thickness coverage, which is desired for this specific application example.

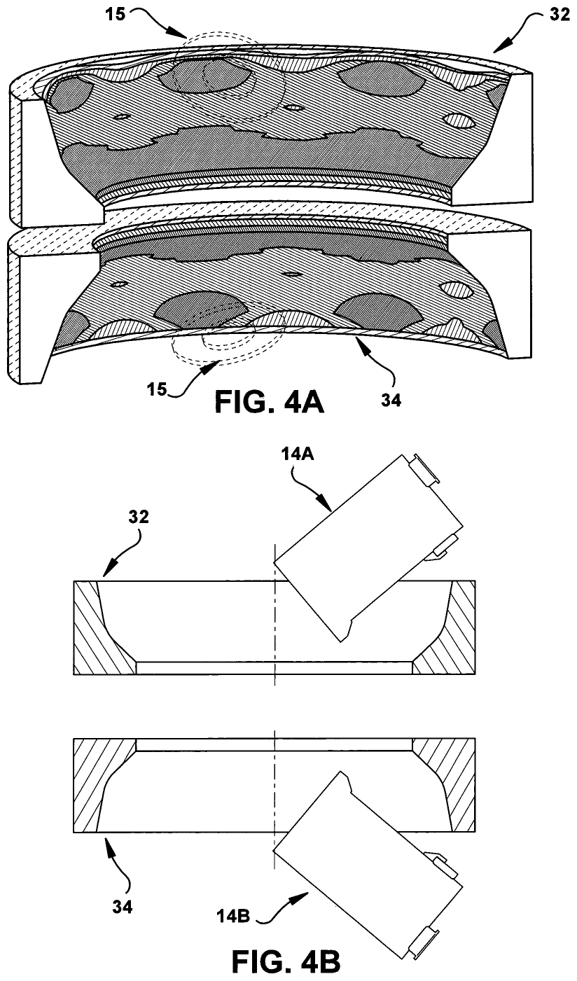

Referring to FIGS. 4a and 4b, according to a second embodiment, the coating assembly 10 may be configured to position the first magnetron 14A adjacent a first liner 32 and the second magnetron 14B adjacent a second liner 34. For clarity, the target surfaces 15 of the first and second magnetrons 14A, 14B are shown in FIG. 4a as ellipses. As illustrated, the first magnetron 14A is oriented toward an inner surface of the first liner 32 and the second magnetron 14B is oriented toward an inner surface of the second liner 34. It is contemplated that with the arrangement of magnetrons 14A, 14B illustrated in FIGS. 4a and 4b, a similar film thickness distribution may be achieved as disclosed for the first embodiment (see FIGS. 3a and 3b).

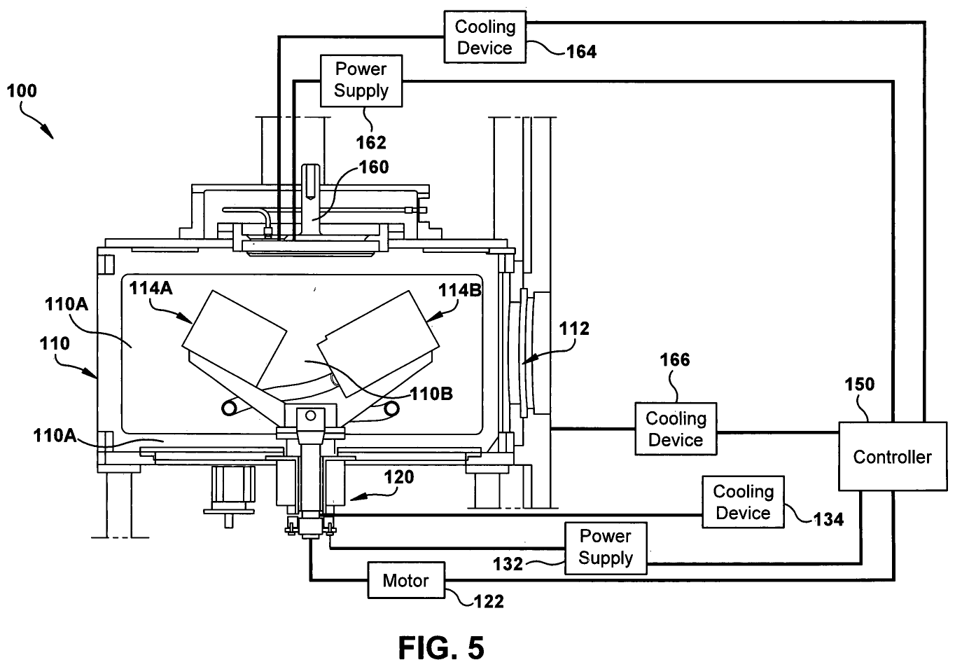

Referring to FIG. 5, a coating assembly 100, according to a third embodiment is illustrated. The coating assembly 100 includes a chamber 110 defined by walls 110a having a door 112 for allowing access to an interior 110b of the chamber 110.

A first magnetron 114A and a second magnetron 114B are positioned within the interior 110b of the chamber 110. In the embodiment illustrated, the first and second magnetrons 114A, 114B are attached to a rotary assembly 120, i.e., similar to a component holder, that extends through one wall 110a of the chamber 110.

The rotary assembly 120 includes a motor 122 that causes the first and second magnetrons 114A, 114B to rotate within the interior of the chamber 110 when commanded to do so by a controller 150. In the embodiment shown, the rotary assembly 120 includes a single axis about which the first and second magnetrons 114A, 114B rotate.

A power supply 132 and a cooling device 134, both controlled by the controller 150, may connect to the first and second magnetrons 114A, 114B via the rotary assembly 120. The power supply 132 (similar to the power supply 16) may be a Bi-polar pulse generator that operates at a predetermined frequency, e.g., 50 kHz-100 kHz. During operation, the first and second magnetrons 114A, 114B may alternate between cathode and anode, as described above in detail.

The cooling device 134 may be configured to provide cooling, e.g., via a cooling fluid such as water, to the first and second magnetrons 114A, 114B, via the rotary assembly 120 during operation. The first magnetron 114A and the second magnetron 114B may have an internal volume that is sealed from the interior 110b of the chamber 110 so that the internal volume the first magnetron 114A and the second magnetron 114B may be maintained at atmospheric pressure while the interior 110b of the chamber 110 is maintained at a vacuum. The internal volume of the magnetrons, maintained at atmospheric pressure, facilitates the technical construction of the rotary assembly.

In the embodiment illustrated in FIG. 5, the component to be coated is an electrostatic chuck 160. The electrostatic chuck 160 is a component that may be used during wafer processing to hold a wafer at a desired location. As understood by those skilled in the art, the electrostatic chuck 160 may include a Mesa surface whereon a wafer is held by electrostatic force. The Mesa surface defines a minimum contact area for the wafer and the electrostatic force allows a helium cushion to be achieved between the electrostatic chuck 160 and the wafer to provide a heat conductive bridge. It is desirable that a height of the Mesa surface be accurate for a uniform electrostatic force. In the embodiment illustrated, a surface of the electrostatic chuck 160 to be coated extends into the interior 110b and faces the first and second magnetrons 114A, 114B. The electrostatic chuck 160 may be connected to a second power supply 162 and a second cooling device 164. The second power supply 162 may be provided to maintain the electrostatic chuck 160 at the desired electrical potential for coating and the second cooling device 164 may be provided to maintain the electrostatic chuck 160 at the desired component temperature for the coating process. It is contemplated that the second power supply 162 may be an RF power supply operating at 13.56 MHz. As illustrated, the controller 150 may control the operation of the second power supply 162 to maintain proper operation of the coating assembly 100. In the embodiment illustrated, the electrostatic chuck 160 is attached to the wall 110a of the chamber 110 and seals an opening in the wall 110a. In this respect, the chamber 110 defines a component holder for the chuck 160.

It is contemplated that the walls 110a of the chamber 110 may be temperature regulated by a third cooling device 166. During operation, the controller 150 may control this third cooling device 166 to maintain the temperature of the chamber 110 at a predetermined chamber temperature that is selected to provide desired coating of the electrostatic chuck 160 or any other component placed within the chamber 110. Prior to venting the chamber 110 to atmosphere, preferably the cooling device 166 may be used to heat the chamber 110 to a predetermined temperature in order to reduced moisture contamination.

It is contemplated that the cooling device 134, the second cooling device 164 and the third cooling device 166 may all use the same fluid source. It also contemplated that they may be separate in distinct fluid devices that separately and independently provide a cooling fluid to their respective components.

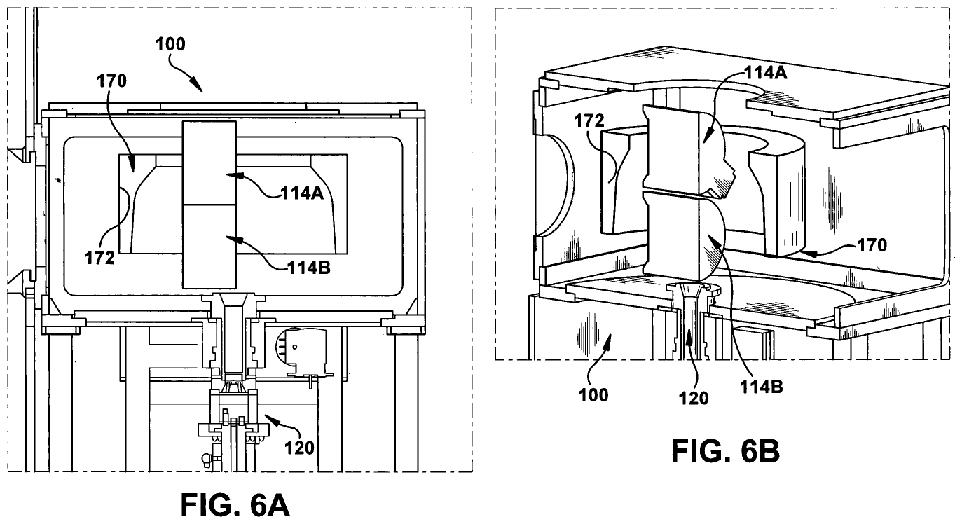

Referring to FIGS. 6a and 6b, in a third embodiment, the coating assembly 100 is configured to receive a liner 170. In the embodiment illustrated, the first and second magnetrons 114A, 114B are positioned and oriented adjacent an inner surface 172 of the liner 170 to direct a coating material onto the inner surface 172. Adjusting the first and second magnetrons 114A, 114B in an angle (see, e.g., FIG. 2) not just in straight line may be beneficial in applying a homogeneous coating to 3D-shaped surfaces to be coated. The first and second magnetrons 114A, 114B are attached to the rotary assembly 120 to rotate within the liner 170. It is also contemplated that the liner 170 itself may rotate with respect the first and second magnetrons 114A, 114B while the magnetrons 114A, 114B are stationary. In order to rotate the liner 170 with respect to the first and second magnetrons 114A, 114B, the liner 170 may be fixed to the rotary assembly 120 instead of the first and second magnetrons 114A, 114B.

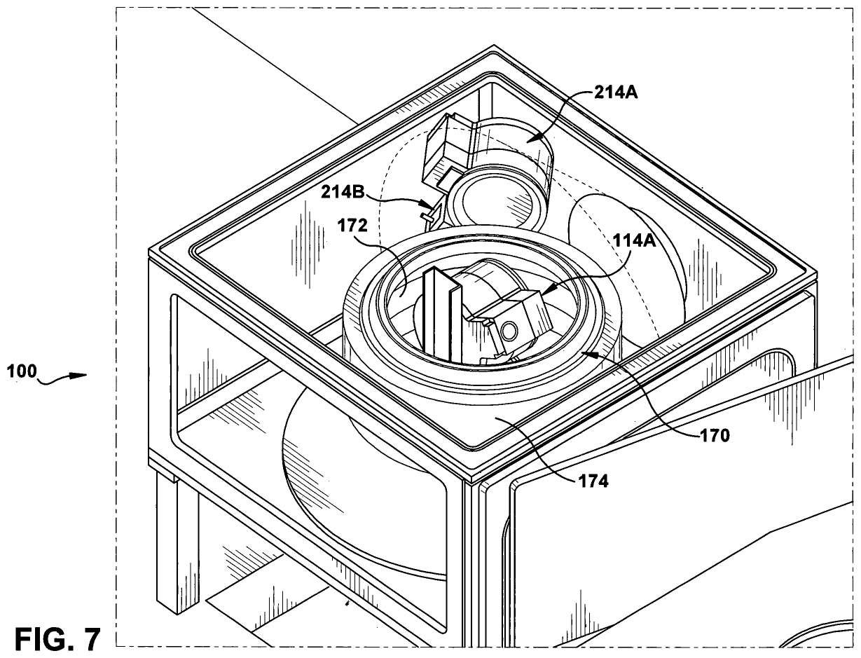

Referring to FIG. 7, in yet another embodiment, the first pair of magnetrons 114A, 114B (the view of the magnetron 114B is obstructed in FIG. 7 by the liner 170) are positioned adjacent the inner surface 172 of the liner 170 while a second pair of magnetrons 214A, 214B are positioned adjacent an outer surface 174 of the liner 170. During operation, the first pair of magnetrons 114A, 114B and the second pair of magnetrons 214A, 214B simultaneous apply a coating film to the inner surface 172 and the outer surface 174, respectively, of the liner 170.

In the embodiments described above wherein the component to be coated is the liner 22, 170, the inventors contemplate that the chamber 12 may be made from aluminum if the coating is oxides or nitrides or the chamber 12 may be made from steel if CF₄ is used as the gas. In these embodiments, the vacuum source 19 may be a pump, e.g., a turbopump. The rotary assembly 120, as described above, may supply water (via the cooling device 134) and/or high voltage and/or biasing voltage (via the power supply 132). In one example, the liner 22, 170 rotates whereas the first and second magnetrons 114A, 114B are stationary. The coating assembly 100 may include a pair of magnetrons 114A, 114B disposed inside a liner (see, FIGS. 6a and 6b) and/or a second pair of magnetrons 214A, 214B disposed outside the liner 170 (see, FIG. 7). The magnetrons 114A, 114B, 214A, 214B may be operated as single magnetrons or dual magnetron pairs. The gas supplied may be, by way of example and not limitation, Ar and/or, O₂ and/or N₂ and/or CF₄. The one or more gas inlet(s) to the chamber 12 are not illustrated in the figures.

In the embodiment described above wherein the component to be coated is the electrostatic chuck 160 or another component with a flat disc-like shape (e.g., a window), the inventors contemplate that the chamber 12 may be made from aluminum and temperature controlled, as illustrated above in FIG. 5. In this embodiment, the vacuum source 19 may be a pump, e.g., a turbopump. The rotary assembly 120, as described above, may supply water (via the cooling device 134) and/or high voltage (via the power supply 132). In one example, the first and second magnetrons 114A, 114B are mounted to the rotary assembly 120 and the electrostatic chuck 160 is stationary. The electrostatic chuck 160 can also function as a lid of the chamber 110, and as such forms part or the wall of the chamber. The coating assembly 100 may include a pair of magnetrons 114A, 114B that may operate as single magnetrons or dual magnetrons. The gas supplied by to the chamber 110 may be, by way of example and not limitation, Ar and/or O₂ and/or N₂.

For the embodiments described above, the coating of the components may be accomplished via reactive sputtering, preferably via reactive dual magnetron sputtering, most preferably via Bi-Polar reactive Dual magnetron sputtering. The following table summarizes the aforementioned operational components:

| | E-Chuck/Windows | |
|---|---|---|
| | flat disc-like | Liner |
| Chamber | Al-walls cooled (because of | Al for oxides, nitrides |
| | pumpdown and outgassing) | or steel if CF₄ is used |
| Rotary | Water, High voltage | Water, high voltage for |
| feedthrough | for magnetrons | Liner cooling and Bias |
| | which are mounted | voltage |
| | on rotary plate | Liner is rotating, |
| | | Magnetron |
| | | are fixed in position |
| Substrate/ | E-chuck is the Lid | Liner is rotated by rot. |
| Liner | of chamber | Feedthrough. |
| | Sealing, RF-Bias, | Water for liner cooling |
| | E-chuck cooling | High voltage for Bias |
| Magnetrons | A pair of Magnetrons | A pair of |
| | rotating with | Magnetrons Inside |
| | respect to flat substrate | Liner or/and a pair of |
| | | magnetrons outside |
| | | Liner |
| Process | Reactive sputtering by discharge voltage | |
| control | control by reactive gas flow | |
| Gases | Ar, O₂, N₂, HMDSO | Ar, O₂, CF₄ |
| Temperature | | Temperature |
| Measurement | | monitoring of |
| and | | the substrate explicitly |
| Control | | linked to the controller |
| Device | | |

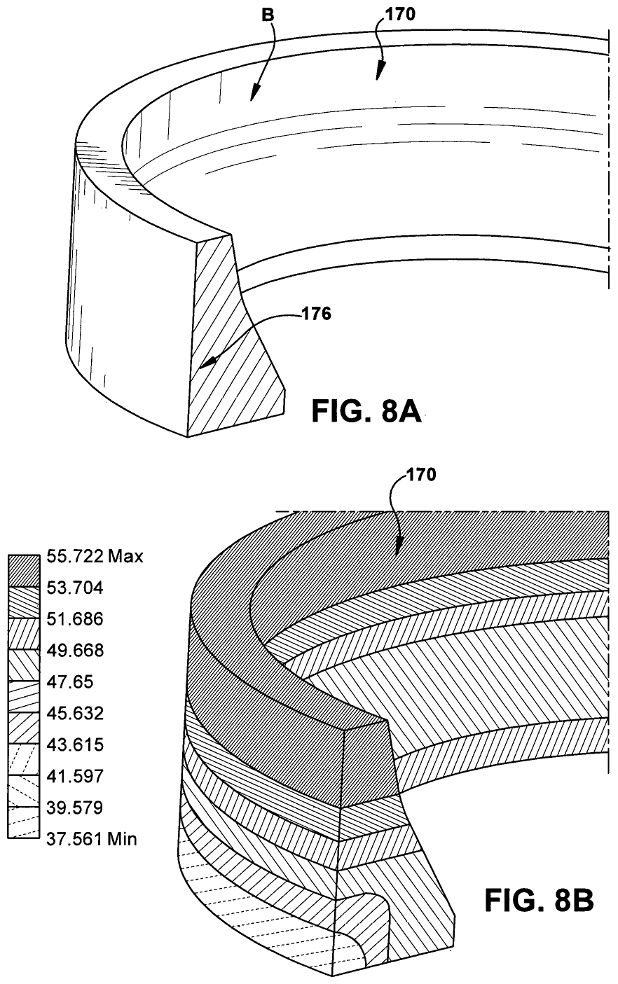

Referring to FIGS. 8a and 8b, as discussed in detail above, various components of the coating assembly 100 may be connected to cooling devices 134, 164 for helping to maintain those components at predetermined temperatures. According to another embodiment, the component to be coated, e.g., the liner 170 may also be in contact with a cooling device e.g., a water cooled clamp along a flange 176 of the liner. When the sputtering flux from the first magnetron 114A or the second magnetron 114B is directed to the liner 170 at the location B (FIG. 8a), the temperature distribution in the liner 170 resulting from the cooling device placed at the flange 176 and the sputtering flux may be as illustrated in FIG. 8b.

Although the aforementioned embodiments have been described with respect to liners and electrostatic chucks, it will be appreciated that those embodiments may be used for applying a coating film to other components of semiconductor equipment.

Although the invention has been described with respect to select embodiments, it shall. be understood that the scope of the invention is not to be thereby limited, and that it instead shall embrace all modifications and alterations thereof coming within the spirit and scope of the appended claims.

1. An apparatus for coating a semiconductor equipment component, the apparatus comprising:
a chamber;
a first magnetron and a second magnetron disposed within the chamber for supplying a coating material to a surface of the component;
a component holder disposed within the chamber and configured to hold the component,
wherein the first magnetron and the second magnetron are configured to be positioned and oriented adjacent the surface of the component held by the component holder and the first and second magnetrons are configured to move with respect to the component holder or the component holder is configured to move with respect to the first and second magnetrons during coating of the component; and
means for flexibly adjusting the position and the orientation of at least one of the first magnetron and the second magnetron with respect to the surface of the component.

2. The apparatus according to claim 1, wherein the movement of the first magnetron and the second magnetron with respect to the component holder is realized in that the component holder is configured in a fix position and the first magnetron and the second magnetron are configured to move within the chamber.

3. The apparatus according to claim 2, wherein the first magnetron and the second magnetron are configured to move while the magnetrons are operating.

4. The apparatus according to claim 1, wherein the component forms at least part of the coating chamber wall through a dedicated adapter, preferably is a chamber wall.

5. The apparatus according to claim 4, wherein the component is an electrostatic chuck or window.

6. The apparatus according to claim 1, wherein the first magnetron and the second magnetron operate with a power supply delivering Bi-polar pulses or as single magnetrons.

7. The apparatus according to claim 1, wherein the component is a liner, an electrostatic chuck or a window.

8. The apparatus according to claim 1, further comprising a third magnetron and a fourth magnetron wherein the component is a liner and the first magnetron and the second magnetron are configured to be disposed adjacent an inner surface of the liner and the third magnetron and the fourth magnetron are configured to be disposed adjacent an outer surface of the liner.

9. The apparatus according to claim 1, wherein the first magnetron and the second magnetron are used together with reactive gas to deposit a film of Al₂O₃, AlN, AlON, AlOF, Y₂O₃, YOF, YAG, YF₃, Er₂O₃, ErOF, DLC or doped DLC or a combination thereof, on the component.

10. The apparatus according to one of the previous claims claim 1, wherein the first magnetron and the second magnetron are mounted on a rotary assembly.

11. The apparatus according to claim 10, where the component holder is mounted on a rotary assembly or is a rotary assembly.

12. The apparatus according to claim 10, wherein at least one of the magnetrons have an internal volume sealed from the interior of the chamber.

13. The apparatus according to claim 12, where the internal volume is maintained at atmospheric pressure when the chamber is maintained at vacuum.

14. The apparatus according to claim 1, wherein the component holder extends through a wall of the chamber.

15. The apparatus according to claim 1, wherein the component holder is a wall of the chamber.

16. The apparatus according to one of the previous claims claim 1, wherein the first and second magnetrons are configured to rotate with respect to the component holder or the component holder is configured to rotate with respect to the first and second magnetrons during coating of the component.

17. A method for coating components, the method comprising:
positioning a component holder in a coating chamber, the component holder configured to hold the component;
positioning and orienting a first magnetron and a second magnetron within the coating chamber adjacent a surface of the component held by the component holder; and
moving the component holder with respect to the first and second magnetrons or moving the first and second magnetrons with respect to the component holder while sputtering a coating from the first magnetron and the second magnetron to the component.

18. The method according to claim 17, the step of moving the component holder with respect to the first and second magnetrons or moving the first and second magnetrons with respect to the component holder includes changing the orientation of the first and second magnetrons with respect to the surface of the component held by the component holder as the component holder moves with respect to the first and second magnetrons or the first and second magnetrons move with respect to the component holder.

19. The method according to claim 17, wherein the component holder is in a fix position while the first and the second magnetrons are moving with respect to the component holder.

20. The method according to claim 19, where the first and second magnetrons are operating while moving with respect to the component holder.

21. The method according to claim 17, the step of moving the component holder with respect to the first and second magnetrons or moving the first and second magnetrons with respect to the component holder includes depositing a film of Al₂O₃, AlN, AlON, AlOF, Y₂O₃, YOF, YAG or YF₃, Er₂O₃, ErOF, DLC or doped DLC or combinations thereof, on the component.

22. The method according to claim 17, wherein the first magnetron and the second magnetron operate with a power supply delivering Bi-polar pulses or as single magnetrons.

23. The method according to claim 17, further comprising depositing with a third magnetron and a fourth magnetron wherein the component is a liner and the first magnetron and the second magnetron are disposed adjacent an inner surface of the liner and the third magnetron and the fourth magnetron are disposed adjacent an outer surface of the liner.

24. The method according to claim 17, wherein the first and second magnetrons are mounted on a rotary assembly.

25. The method according to claim 24, wherein the component holder is mounted on a rotary assembly or is a rotary assembly.

26. The method according to claim 17, wherein the component holder extends through a wall of the coating chamber.

27. The method according to claim 17, wherein the component holder together with the component is at least part of a wall of the coating chamber.

28. The method according to claim 17, wherein the step of moving the component holder with respect to the first and second magnetrons or moving the first and second magnetrons with respect to the component holder includes rotating the component holder with respect to the first and second magnetrons or rotating the first and second magnetrons with respect to the component holder.
